(19) United States
(12) Patent Application Publication
(10) Pub. No.: US 2009/0230570 A1
(43) Pub. Date: Sep. 17, 2009

(54) RESIN COMPOSITION AND SEMICONDUCTOR DEVICE EMPOLYING THE SAME

(76) Inventors: Taro Fukaya, Kawasaki-Shi (JP); Shinetsu Fujieda, Kawasaki-Shi (JP); Tatsuoki Kohno, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/401,095

(22) Filed: Mar. 10, 2009

(30) Foreign Application Priority Data
Mar. 12, 2008 (JP) 2008-62320

(51) Int. Cl. H01L 23/29; C09D 163/02

(52) U.S. Cl. 257/793; 523/466; 523/223; 257/E23.119

(57) ABSTRACT

The present invention provides a resin composition for sealing a semiconductor device. The resin composition is in liquid state at room temperature, and can be supplied from a dispenser. The composition is advantageous in regard to molding time, viscosity, moldability and adhesion. This resin composition indispensably comprises a bisphenol type epoxy resin having a polymerization degree of 3 or less, a particular phenol resin or a particular acid anhydride, a catalyst (A) such as 1-cyanoethyl-2-undecylimidazolium trimellitate, a catalyst (B) such as 1-cyanoethyl-2-ethyl-4-methylimidazol, and spherical fused silica particles. The weight ratio (A/B) between the catalysts (A) and (B) is in the range of 9/1 to 4/6.

### CROSS-REFERENCE TO RELATED APPLICATION

This application is based upon and claims the benefit of priority from the prior Japanese Patent Application No. 62320/2008, filed on Mar. 12, 2008; the entire contents of which are incorporated herein by reference.

### BACKGROUND OF THE INVENTION

1. Field of the Invention

The present invention relates to a resin composition for sealing a semiconductor device. In detail, this invention relates to a liquid resin composition excellent in reflow resistance and durability for pressure cooker test.

2. Background Art

A semiconductor device is generally sealed with a molding material for sealing semiconductors and is thereby protected from mechanical stresses such as shock and pressure and/or from external environments such as foreign substances, humidity, heat and UV light, so that the electrical insulation can be ensured and that the device can be easily installed on a substrate. The sealing procedure is normally carried out according to transfer molding method. However, in a transfer molding machine for the method, waste resin is often left in the runner and cull. Accordingly, since extra resin is thus consumed, this molding method is very poor in efficiency. Further, in the method, since the resin is made to flow under high pressure, silica or the like contained in the resin may scratch the mold surface in the molding machine to generate powdery metal fragments, which may contaminate the resultant semiconductor device.

In addition, the transfer molding method has another problem from the viewpoint of resin properties. In consideration of treatability, resin currently used in the transfer molding method is a polymer compound in solid state at room temperature. Accordingly, with respect to adhesion to copper, the resin compound has a small number of functional groups that interact with the copper surface. Consequently, the resultant device often breaks at the interface when subjected to reflow treatment or to pressure cooker test (hereinafter, referred to as “PCT”). If a compound of low molecular weight is used, the interactive functional groups are so increased that the adhesion strength to copper can be expected to be improved. However, on the other hand in that case, since the hardening reaction starts from the compound of low molecular weight, the reaction is difficult to be controlled and hence properties other than the adhesion strength may deteriorate when the hardening reaction proceeds rapidly.

JP-A 2000-169537 (KOKAI) describes a hardening agent for sealing semiconductors. The hardening agent comprises a liquid phenol novolac type resin, and is expected to be used as an advantageous liquid sealant for semiconductors. However, in the publication, there are insufficient descriptions of preferred catalysts and of how to solve the problems occurring when the resin is rapidly hardened, and accordingly there is room for improvement to use the hardening agent in practice. Thus, hitherto there has not been found a liquid semiconductor device-sealing resin having not only excellent durability for PCT and reflow treatment but also satisfying other properties.

JP-A 2000-7891 (KOKAI) also discloses a semiconductor-sealing resin derived from acid anhydride. The disclosed resin is expected to be used as an advantageous liquid semiconductor sealant. However, the publication is silent about preferred catalysts and about how to ensure the adhesion strength to copper, particularly, after subjected to PCT and reflow treatment although the adhesion strength to copper is indispensably required of the resin for sealing a semiconductor device.

### SUMMARY OF THE INVENTION

The present invention resides in a resin composition comprising:

(I) a resin component (a) selected from bisphenol type epoxy resins having polymerization degrees of 3 or less;
(II) a component (b) selected from the group consisting of:
(ii) phenol resins represented by the formula (1A):

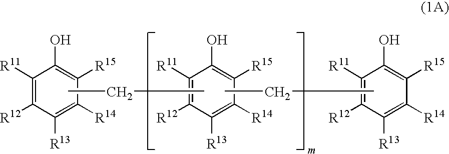

wherein m is a number of 0 to 3, and each of R¹¹ to R¹⁵ is H or an allyl group provided that at least one of R¹¹ to R¹⁵ is an allyl group, and
(ii) acid anhydrides represented by the formula (1B):

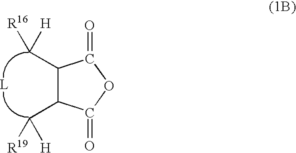

where L is a divalent linking group represented by

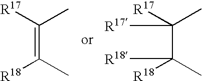

and each of R¹⁶, R¹⁷, R^{17′}, R¹⁸, R^{18′} and R¹⁹ is independently H or a hydrocarbon group containing 8 or less carbon atoms provided that at least two of R¹⁶, R¹⁷, R^{17′} R¹⁸, R^{18′} and R¹⁹ are hydrocarbon groups;
(III) a catalyst (A) represented by one of the formulas (2A), (2B) and (2C):

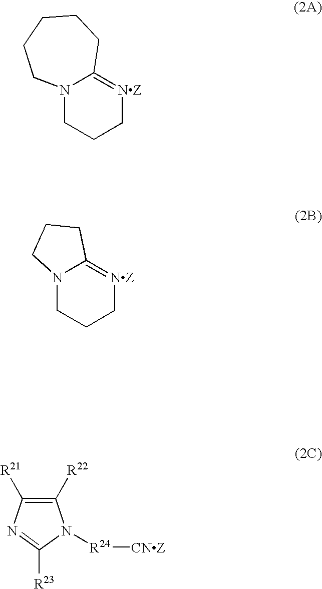

wherein each of R²¹ to R²⁴ is H or a hydrocarbon group which may be substituted with hydroxyl or cyano, and Z is a compound selected from the group consisting of sulfonic acids, carboxylic acids, phenols and phenol resins;
(IV) a catalyst (B) represented by one of the formulas (3A), (3B) and (3C):

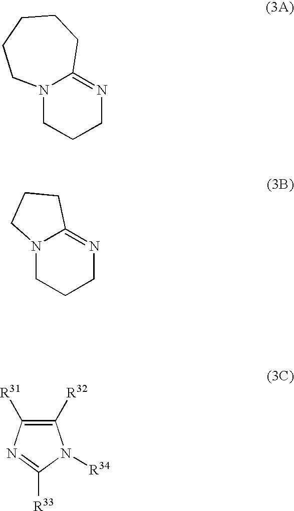

where each of R³¹ to R³⁴ is H or a hydrocarbon group which may be substituted with hydroxyl or cyano; and
(V) spherical fused silica particles;
under the condition that the weight ratio (A/B) between the catalyst (A) and the catalyst (B) is in the range of 9/1 to 4/6.

The present invention also resides in a semiconductor device characterized by being sealed with the above resin composition.

The resin composition according to the present invention can be used as a semiconductor-sealing resin composition in liquid state at room temperature. Since the composition is liquid, it can be supplied to a cavity of the mold by means of a dispenser. This means that the mold surface is not scratched and that waste resin is not left in the runner and cull, and accordingly the cost of molding can be remarkably reduced. Further, the resin composition of the present invention is excellent in various properties, such as time for molding, viscosity and obtained hardness. In addition, the composition is also excellent in PCT durability and in adhesion strength at the interface of copper/resin even after subjected to reflow treatment. Accordingly, the resin composition is industrially very advantageous in view of both production efficiency and product performance.

### DETAILED DESCRIPTION OF THE INVENTION

### Resin Component (a))

In one embodiment of the present invention, the resin composition contains a resin component (a) selected from bisphenol type epoxy resins having polymerization degrees of 3 or less. The “bisphenol type epoxy resin having a polymerization degree of 3 or less” means a resin which contains one or more, preferably, two or more epoxy groups and which includes one to three bisphenol structures in its molecular structure. The bisphenol type epoxy resin is, for example, represented by the formula (4).

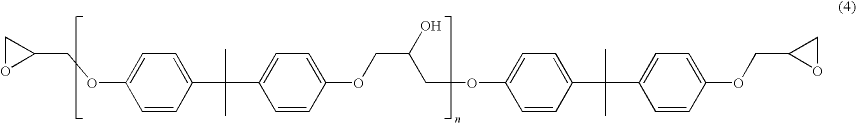

The formula (4) contains one bisphenol structure outside of the repeating unit, and hence the polymerization degree is 3 or less when the average of n, which indicates the polymerization degree, is in the range of 0 to 2. The bisphenol structure is, for example, bisphenol A type structure, bisphenol F type structure or bisphenol S type structure. The formula (4) is an example of the resin comprising the bisphenol A type structure. In the present invention, an epoxy resin having the bisphenol A type structure is preferred because strong adhesion strength can be obtained.

### Component (b)

In one embodiment of the present invention, the resin composition contains a component (b) selected from the group consisting of particular phenol resins and particular acid anhydrides.

The phenol resins usable as the component (b) in the present invention are represented by the formula (1A).

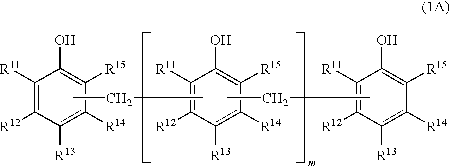

In the above formula, m is a number of 0 to 3, and each of R¹¹ to R¹⁵ is H or an allyl group provided that at least one of R¹¹ to R¹⁵ is an allyl group. The repeating units may individually contain different allyl groups.

In the present invention, the phenol resin represented by the formula (1A) has a phenol novolac structure, in which at least one of R¹¹ to R¹⁵ is substituted with an allyl group. A phenol resin not substituted with an allyl group is unsuitable for the resin composition of the present invention. The reason of that is because the phenol resin having an allyl group prevents the viscosity of the resin composition from increasing and thereby makes it easy to supply the composition from a dispenser. There is no particular restriction on the polymerization degree, and hence the number of m is not particularly limited. However, the polymerization degree is preferably so controlled that the melting point or the softening point may be 70° C. or below.

The above phenol resin is commercially available, for example, from Meiwa Plastic Industries, LTD. (e.g., MEH-8000H, MEH-8005, MEH-8010, MEH-8015™), and hence can be easily obtained.

The acid anhydrides usable in the present invention are represented by the formula (1B).

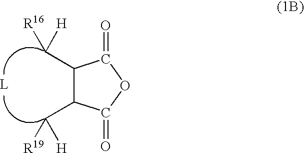

In the above formula, L is a divalent linking group represented by

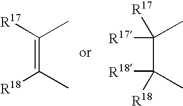

and each of R¹⁶, R¹⁷, R^{17′}, R¹⁸, R^{18′} and R¹⁹ is independently H or a hydrocarbon group containing 8 or less carbon atoms provided that at least two of R¹⁶, R¹⁷, R^{17′}, R¹⁸, R^{18′} and R¹⁹ are hydro-carbon groups. Examples of the hydrocarbon group include an alkyl group, an alkenyl group, an allyl group, and an aryl group each of which contains 10 or less carbon atoms. The hydro-carbon group may have an unsaturated carbon bond or may have a branched structure. In the acid anhydride, typically as in nadic acid anhydride, the groups of R¹⁶ and R¹⁹ may be connected. The hydrocarbon group is preferably methyl, ethyl, propyl, propenyl or isopropenyl.

It is necessary that at least two of R¹⁶, R¹⁷, R^{17′}, R¹⁸, R^{18′} and R¹⁹ be substituted with a hydrocarbon group containing 8 or less carbon atoms. An acid anhydride containing one or no hydrocarbon group is unsuitable for the resin composition of the present invention. The reason of that is because the acid anhydride having at least two alkyl groups prevents the viscosity of the resin composition from increasing and thereby makes it easy to supply the composition from a dispenser. Further, the PCT durability is also so improved that the resin composition can bear PCT for a long time.

Examples of the acid anhydride include methylnadic acid anhydride, nadic acid anhydride, hydrogenized methylnadic acid anhydride, hydrogenized nadic acid anhydride, and a trialkyl tetrahydrophthalic acid anhydride (e.g., 3,4-dimethyl-6-(2-methyl-1-propenyl)-4-cyclohexene-1,2-dicarboxylic acid anhydride).

Two or more components (b) can be used in combination.

### (Catalyst (A))

In one embodiment of the present invention, the resin composition contains a particular catalyst (A). The catalyst (A) is represented by one of the formulas (2A), (2B) and (2C).

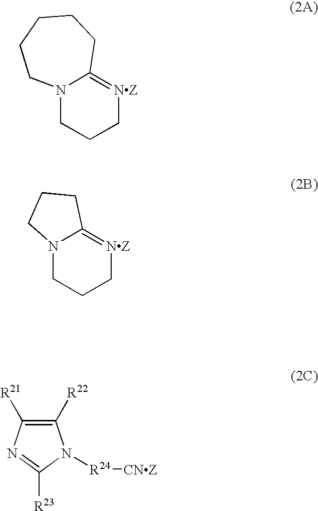

In the formulas, each of R²¹ to R²⁴ is H or a hydrocarbon group containing 8 or less carbon atoms. The hydrocarbon group may be substituted with hydroxyl or cyano. Further, the hydrocarbon group may be either an aliphatic hydrocarbon group or an aromatic hydrocarbon group such as a phenyl group. In the formula, Z is a compound selected from the group consisting of sulfonic acids, carboxylic acids, phenols and phenol resins.

Examples of the catalyst (A) include 1-cyano-ethyl-2-undecylimidazolium trimellitate, 1-cyanoethyl-2-phenyl-imidazolium trimellitate, phenol salts of 1,8-diazabicyclo-(5,4,0)-undecene-7 (hereinafter, referred to as “DBU”), octylic acid salts of DBU, p-toluenesulfonic acid salts of DBU, formic acid salts of DBU, ortho-phthalic acid salts of DBU, phenol novolac resin salts of DBU, tetraphenylborates of DBU derivatives, and phenol novolac salts of 1,5-diazabicyclo-(4,3,0)-nonene-5 (hereinafter, referred to as “DBN”). Among them, 1-cyanoethyl-2-undecylimidazolium trimellitate is preferred because it increases the adhesion strength.

The above catalyst (A) is commercially available, for example, from Shikoku Chemicals Corp. (e.g., C11ZCNS, 2PZCNS-PW™) or from SAN-APRO Ltd. (e.g., U-CAT SA1, SA102, SA506, SA603, SA831, SA841, SA851, 881 or 5002™).

### (Catalyst (B))

In one embodiment of the present invention, the resin composition contains a particular catalyst (B). The catalyst (B) is represented by one of the formulas (3A), (3B) and (3C).

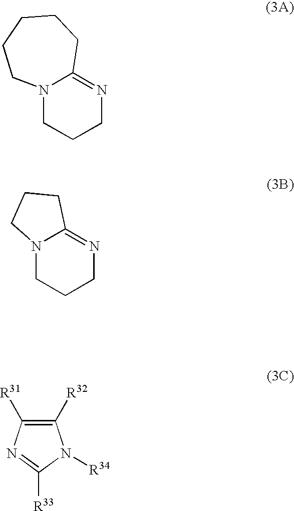

In the formula, each of R³¹ to R³⁴ is H or a hydrocarbon group containing 8 or less carbon atoms. The hydrocarbon group may be substituted with hydroxyl or cyano. Further, the hydrocarbon group may be either an aliphatic hydrocarbon group or an aromatic hydrocarbon group such as a phenyl group.

Examples of the catalyst (B) include 2-methylimidazole, 2-undecylimidazole, 2-heptadecylimidazole, 1,2-dimethyl-imidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyano-ethyl-2-ethyl-4-methylimidazole, 1-cyanoethyl-2-phenyl-imidazole, 2-phenyl-4,5-dihydroxymethylimidazole, 2-phenyl-4-methyl-5-hydroxymethylimidazole, and 1,8-diazabi-cyclo(5,4,0)-undecene-7,1,5-diazabicyclo(4,3,0)-nonene-5 (hereinafter, referred to as “DBN”). Among them, 1-cyano-ethyl-2-ethyl-4-methylimidazole and 2-phenylimidazole are preferred because they reduce the viscosity of the resin composition and thereby make it easy to supply the composition from a dispenser.

The above catalyst (B) is commercially available, for example, from Shikoku Chemicals Corp. (e.g., 2MZ, 2MZ-P, C11Z, C17Z, 1.2DMZ, 2E4MZ, 2PZ, 2PZ-PW, 2P4MZ, 1B2MZ, 1B2PZ, 2MZ-CN, C11Z-CN, 2E4MZ-CN, 2PZ-CN, 2PHZ-PW or 2P4 MHZ-PW™), and the above DBU and DBN are also commercially available from SAN-APRO Ltd.

### (Amounts and Ratio of Catalysts (A) and (B))

The composition contains the catalysts (A) and (B) so that the weight ratio of (A/B) is indispensably in the range of 9/1 to 4/6, preferably in the range of 9/1 to 5/5. If the amount of the catalyst (A) is smaller, the resin composition hardens rapidly when a semiconductor device is sealed with the composition in the mold, and consequently the production efficiency is improved. Further, the hardened composition is hardly broken when released from the mold. The catalyst (A) is, therefore, preferably contained the composition in a smaller amount. On the other hand, however, if the amount of the catalyst (B) is smaller, the viscosity of the composition hardly increases in the below-described kneading step and hence is easily so controlled that the resultant composition can be supplied from a dispenser.

The total amount of the catalysts (A) and (B) is preferably 0.5 to 2 wt. %, more preferably 1 to 1.5 wt. % based on the total weight of the resin composition. The total amount of the catalysts is preferably not less than 0.5 wt. % in order that the composition can have both sufficient PCT durability and rapid hardening speed and further that the composition after hardened may be hardly broken when released from the mold. On the other hand, however, if the total amount of the catalysts is more than 2 wt. %, the composition is hardened so rapidly that the hardened product has poor strength and, as a result, that the adhesion strength is lowered. Accordingly, the total amount of the catalysts is preferably 2 wt. % or less.

### (Spherical Fused Silica Particles)

In one embodiment of the present invention, the resin composition contains spherical fused silica particles. The spherical fused silica particles are normally produced by melting silica stone as the raw material in flames at a high temperature and then forming spherical particles from the melt by use of its surface tension. The spherical fused silica particles used in the present invention are not particularly restricted as long as they are spherical silica particles. In generally used spherical fused silica particles, particles of irregular shapes are often mixed. Also the spherical fused silica particles used in the present invention may be mingled with particles of irregular shapes as long as spherical particles are the main component. There is no particular restriction on the particle size, but the mean particle size is generally in the range of 1 to 50 μm. The spherical fused silica particles preferably have a maximum particle size of 10 to 200 μm. In consideration of treatability, the maximum particle size is preferably smaller than 1/10 of the inner diameter of a dispenser used in sealing a semiconductor device.

### (Optional Resin Component)

In one embodiment of the present invention, the resin composition can contain other resin components. Examples of the optional resin component include phenol resins other than those represented by the formula (1A) used as the component (b). Examples of such phenol resins include phenol novolac resins, xylylene novolac resins and biphenyl novolac resins. There is no particular restriction on the polymerization degrees of these phenol resins, but their softening points are preferably 70° C. or below so that the composition can be easily supplied from a dispenser to seal a device. The optional phenol resins are, for example, represented by the following formulas (5A) to (5C).

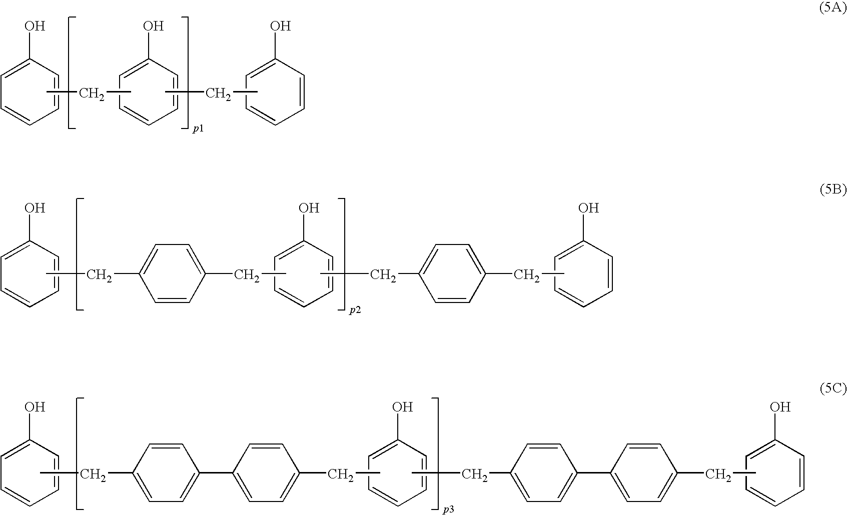

In the above formulas, p1, p2 and p3 are numbers indicating polymerization degrees.

### (Mixing and Kneading of the Resins)

For mixing the resin component (a), the component (b), the catalyst (A), the catalyst (B) and the spherical fused silica particles, any known means can be used. Those components are homogeneously mixed by means of, for example, three-roll mixing machine, ball mill, smash-mixing machine, homogenizer, planetary mixer, multipurpose mixer, extruder, or Henschel mixer. There is no particular restriction on the order of mixing. However, preferably the resin components and the spherical fused silica particles are mixed first and then the catalysts (A) and (B) are mixed therein at a low temperature so that the reaction in mixing can be avoided to obtain a composition of low viscosity.

In the present invention, there is no particular restriction on the mixing ratio of each component. However, it is preferred that the weight ratio of the resin component (a) be in the range of 10 to 20 wt. %, that the weight ratio of the component (b) be in the range of 4 to 15 wt. %, that the total weight ratio of the catalysts (A) and (B) be in the range of 0.5 to 2 wt. % and that the weight ratio of the spherical fused silica particles be the residual amount, namely, in the range of 75 to 85 wt. % based on the total weight of the resin composition.

In the case where the component (b) is a phenol resin represented by the formula (1A), the amount thereof is preferably in the range of 4 to 12 wt. %.

Also in the case where a phenol resin represented by the formula (1A) is used in the present invention, one of the most preferred resin compositions comprises: a bisphenol A type epoxy resin having a polymerization degree of 3 or less (resin component (a)) in an amount of 10 to 15 wt. %, a phenol resin of the formula (1A) (component (b)) in an amount of 5 to 10 wt. %, 1-cyanoethyl-2-undecylimidazolium trimellitate (catalyst (A)) in an amount of 0.5 to 1.5 wt. %, 1-cyano-ethyl-2-ethyl-4-methylimidazole (catalyst (B)) in an amount of 0.25 to 0.8 wt. %, and spherical fused silica particles in the residual amount, namely, in an amount of 75 to 82 wt. %.

Further, in the case where the component (b) is an acid anhydride represented by the formula (1B), the amounts of the components (a) and (b) are preferably in the ranges of 10 to 15 wt. % and 10 to 15 wt. %, respectively. If containing an optional phenol resin other than those represented by the formula (1A), the resin composition of the present invention preferably comprises: a bisphenol type epoxy resin having a polymerization degree of 3 or less in an amount of 10 to 15 wt. %, an acid anhydride of the formula (1B) in an amount of 5 to 12 wt. %, the catalysts (A) and (B) in a total amount of 0.5 to 2 wt. %, spherical fused silica particles in an amount of 75 to 85 wt. %, and an optional phenol resin represented by one of the formulas (5A) to (5C) in an amount of 3 to 5 wt. %.

Also in the case where an acid anhydride represented by the formula (1B) is used in the present invention, one of the most preferred resin compositions comprises: a bisphenol type epoxy resin having a polymerization degree of 2 or less in an amount of 10 to 15 wt. %, an acid anhydride of the formula (1B) in an amount of 10 to 15 wt. %, the catalysts (A) and (B) in a total amount of 0.5 to 2 wt. %, and spherical fused silica particles in an amount of 75 to 85 wt. %.

Still also in the case where an acid anhydride represented by the formula (1B) is used in the present invention, another of the most preferred resin compositions comprises: a bisphenol type epoxy resin having a polymerization degree of 3 or less in an amount of 10 to 15 wt. %, an acid anhydride of the formula (1B) in an amount of 5 to 12 wt. %, the catalysts (A) and (B) in a total amount of 0.5 to 2 wt. %, spherical fused silica particles in an amount of 75 to 85 wt. %, and an optional phenol resin represented by one of the formulas (5A) to (5C) in an amount of 3 to 5 wt. %.

### (Measurement of Adhesion Strength to Copper)

The resin composition according to the present invention has such an excellent property that it can keep sufficient adhesion strength to copper even after subjected to PCT or reflow treatment. The adhesion strength can be evaluated by the test of tensile-shear adhesion strength at 25° C. in accordance with JIS K 6850.

The PCT is carried out under the saturated vapor pressure of water at 127° C. for 96 hours. In the reflow test, a sample after soaked with water for 96 hours in the PCT is then passed through a reflow furnace at 280° C. for 30 seconds. After passed through the reflow furnace for 30 seconds, the sample is cooled in air and again passed through the reflow furnace. This procedure is repeated three times to complete the reflow test. Instead of being passed through the reflow furnace, the sample may be wrapped in aluminum foil and immersed in solder bath at 280° C. for 30 seconds.

The adhesion strength is evaluated in accordance with JIS K 6850. First, a piece of oxygen-free copper having a predetermined size is washed twice with acetone by means of an ultrasonic cleaner. After the sample is dried, the resin composition is applied on a predetermined area of the sample and is then hardened in an oven. In the present invention, the composition is first hardened at 150° C. to 175° C. for 5 to 30 minutes and then secondly hardened at 175° C. for 4 to 10 hours. The obtained sample is subjected to the PCT and the reflow test to measure the strength of the sample.

The hardened product obtained from the resin composition of the present invention is characterized by having an adhesion strength in the range of 0.4 MPa or more, preferably 1.0 MPa or more, after subjected to the PCT and reflow treatment.

(Semiconductor Device Sealed with the Resin Composition)

The resin composition according to the present invention is advantageously used as a sealant of semiconductor devices. The composition of the present invention can be easily supplied from a dispenser, and hence makes relatively small loss as compared with transfer molding method. Accordingly, semiconductor devices can be efficiently sealed with the composition. The sealing process comprises the steps of, for example, fixing a semiconductor device on a flame, setting the device together with the flame in a cavity of mold, pouring the resin composition into the cavity from a dispenser, and heating the composition to harden to seal the semiconductor device. There is no particular restriction on the conditions for hardening the composition. However, the components of the resin composition are preferably so controlled that the gel time at 150° C. or 175° C. may be within 60 seconds and thereby that the composition can be hardened at 150° C. to 175° C. within 1 to 5 minutes.

The present invention is further explained by use of the following examples. Materials used in the examples are as follows.

### (Materials Used in the Examples)

### (1) Resin Component (a)

Epoxy a-1: bisphenol A type epoxy resin (EP4100E™, available from ADEKA Corp.); average polymerization degree: 0.18 (n=0: 84%, n=1: 14%, n=2: 2%, n>2: 0%),

Epoxy a-2: bisphenol F type epoxy resin (807™, available from Japan Epoxy Resin Co., Ltd.); average polymerization degree: 0.26 (n=0: 83%, n=1: 8%, n=2: 9%, n>2: 0%),

Epoxy a-3: bisphenol A type epoxy resin (1001™, available from Japan Epoxy Resin Co., Ltd.); average polymerization degree: 4.17 (n=0: 10.7%, n=1: 13.3%, n=2: 12.5%, n=3: 10.8%, n=4: 9.0%, n=5: 7.4%, n=6: 6.7%, n=7: 3.9%, n≧8: 25.7%).

### (2) Component (b)

Phenol b-A1: ally group-containing phenol novolac resin in liquid state at room temperature (MEH-8000H™, available from Meiwa Plastic Industries, LTD.),

Phenol b-A2: phenol novolac resin (H-1™, available from Meiwa Plastic Industries, LTD.); softening point: 84° C.,

Acid anhydride b-B1: 3,4-dimethyl-6-(2-methyl-1-propenyl)-4-cyclohexene-1,2-dicarboxylic acid anhydride (YH-306™, available from Japan Epoxy Resin Co., Ltd.),

Acid anhydride b-B2: methylnadic acid anhydride (KAYAHARD MCD™, available from Nippon Kayaku Co., Ltd.),

Acid anhydride b-B3: methyl tetrahydrophthalic acid anhydride (QH-200™, available from Zeon Corp.).

### (3) Catalyst (A)

Catalyst A-1: 1-cyanoethyl-2-undecylimidazolium trimellitate (C11Z-CNS™, available from Shikoku Chemicals Corp.),

Catalyst A-2: phenol novolac resin salt of DBU (U-CAT SA841™, available from SAN-APRO Ltd.),

Catalyst A-3: tetraphenylborate of DBU (U-CAT SA5002™, available from SAN-APRO Ltd.),

Catalyst A-4: p-toluenesulfonic acid salt of DBU (U-CAT SA506™, available from SAN-APRO Ltd.).

### (4) Catalyst (B)

Catalyst B-1:1-cyanoethyl-2-ethyl-4-methylimidazole (2E4MZ-CN™, available from Shikoku Chemicals Corp.),

Catalyst B-2: 2-phenylimidazole (2PZ™, available from Shikoku Chemicals Corp.),

Catalyst B-3: 1,8-diazabicyclo(5,4,0)-undecene-7(DBN),

Catalyst B-4: 2-phenyl-4,5-dihydroxymethylimidazole (2PHZ-PW™, available from Shikoku Chemicals Corp.).

### (5) Spherical Fused Silica Particles

Silica-1: spherical fused silica particles (mean particle size: 14.5 μm; S610P™, available from Micron Co., Ltd.),

Silica B-2: spherical fused silica particles (mean particle size: 7.4 μm; MSS-7™, available from Tatsumori Ltd.),

Epoxy silane: epoxy silane (SH-6040™, available from Dow Corning Toray Co., Ltd.).

### (6) Optional Resin Component

Phenol-1: xylylene novolac resin (MILEX XLC-4L™, available from Mitsui Chemicals Inc.); softening point: 63° C.,

Phenol-2: biphenyl novolac resin (MEH-7851™, available from Meiwa Plastic Industries, LTD.); softening point: 70° C.

The resin composition was evaluated by the following tests.

Test for Supplying from Dispenser

It was confirmed by eye whether the resin composition heated at 40° C. could be supplied from a needle having an inner diameter of 2 mm at the tip.

### Storage Test

The resin composition was loaded in a syringe and heated at 40° C., and left for 3 hours. Thereafter, it was confirmed by eye whether the composition could be supplied from a needle having an inner diameter of 2 mm at the tip.

Adhesion Strength to Copper after PCT and Reflow Treatment

An oxygen-free copper plate beforehand washed with acetone was placed on a hot-plate heated at 175° C., and then the resin composition was applied on the copper plate in an area regulated by JIS K 6850. Thereafter, another copper plate having the same size was placed thereon and left for 5 minutes to harden the composition. Further, the composition was hardened at 150° C. for 4 hours and 175° C. for 4 hours to obtain an initial sample. After subjected to PCT at 127° C. for 96 hours so as to be soaked with water, the sample was warped in aluminum foil and then immersed in solder bath at 280° C. for 30 seconds, followed by cooling to room temperature. The immersion was repeated three times, and cooled to room temperature. The adhesion strength of the thus treated sample to copper was measured in accordance with JIS K 6850.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

### EXAMPLES

### Example 1

### Preparation of Resin Composition

In a multipurpose mixer (2DMV-R™, available from Dalton Co., Ltd.), 12.73 wt. % of Epoxy a-1, 3.14 wt. % of Phenol b-A1, 0.5 wt. % of Epoxy silane and Silica-1 were placed and mixed at 80° C. for 2 hours while the mixing chamber was being evacuated. Thereafter, the temperature was brought down to 60° C., and then a solution in which 1 wt. % of Catalyst A-1 and 0.5 wt. % of Catalyst B-1 were dissolved in 3 wt. % phenol was added and mixed for 10 minutes to obtain a resin composition. In the above, Silica-1 was added in the residual amount, which corresponded to the difference between the weight of the resultant composition and the total weight of the other components. The obtained composition could be supplied from a dispenser, and was found to be excellent in storage stability. It was also found that the adhesion strength of the composition to copper was 830 kPa after the PCT and reflow treatment.

### Comparative Example 1

With respect to a commercially available transfer-molding type resin composition mainly comprising cresol novolac type epoxy resin, phenol novolac resin, spherical silica particles and triphenylphosphine, the adhesion strength to copper after the PCT and reflow treatment was measured in the same manner. As a result, ⅔ of the sample pieces were peeled and the average adhesion strength of the other sample pieces was 130 kPa. This result indicated that the transfer-molding type resin composition of Comparative Example 1 scarcely had adhesion strength to copper. Further, since the composition was solid at room temperature, it could not be supplied from a dispenser. In addition, since the viscosity could not be measured at 40° C., the storage stability could not be evaluated.

### Comparative Example 2

With respect to a commercially available liquid sealant resin composition mainly comprising bisphenol A type epoxy resin, methyl tetrahydrophthalic acid anhydride, spherical silica particles and 2-ethyl-4-methylimidazole, the adhesion strength to copper after the PCT and reflow treatment was measured in the same manner. As a result, all the sample pieces were peeled after the reflow treatment. (This meant that the adhesion strength was 0 kPa.) The result indicated that the liquid sealant resin composition of Comparative Example 2 had no adhesion strength to copper. The composition could be supplied from a dispenser. Further, although the viscosity was increased, the composition was usable even after stored.

### Examples 2 to 9 and Comparative Examples 3 to 6

The procedure of Example 1 was repeated, except that the catalysts, the resin components and the amounts thereof were changed into those shown in Table 1, to prepare resin compositions. With respect to each prepared composition, it was evaluated how much adhesion strength to copper the composition had after the PCT and reflow treatment, whether the composition could be molded, whether the composition could be supplied from a dispenser and whether the composition had satisfying storage stability. The components and the results were as set forth in Table 1.

TABLE 1

| | Examples | | | | | | | | | Comparative examples | | | |
|---|---|---|---|---|---|---|---|---|---|---|---|---|---|
| | 1 | 2 | 3 | 4 | 5 | 6 | 7 | 8 | 9 | 3 | 4 | 5 | 6 |
| Epoxy a-1 | 12.73 | 12.73 | 12.73 | 12.73 | 12.73 | 12.73 | 12.73 | 10.83 | 11.82 | 12.73 | 12.73 | 12.73 | 12.73 |
| Phenol b-A1 | 6.14 | 6.14 | 6.14 | 6.14 | 6.14 | 6.14 | 6.14 | 8.04 | 7.05 | 6.14 | 6.14 | 6.14 | 6.14 |
| Epoxy silane | 0.5 | 0.5 | 0.5 | 0.5 | 0.5 | 0.5 | 0.5 | 0.5 | 0.5 | 0.5 | 0.5 | 0.5 | 0.5 |
| Catalyst A-1 | 1 | 1 | 1 | 1 | | | | 1 | 1 | 1 | 1.5 | | |
| Catalyst A-2 | | | | | 1 | | | | | | | | |
| Catalyst A-3 | | | | | | 1 | | | | | | | |
| Catalyst A-4 | | | | | | | 1 | | | | | | |
| Catalyst B-1 | 0.5 | | | | 0.5 | 0.5 | 0.5 | 0.5 | 0.5 | | | 0.5 | 1.5 |
| Catalyst B-2 | | 0.5 | | | | | | | | | | | |
| Catalyst B-3 | | | 0.5 | | | | | | | | | | |
| Catalyst B-4 | | | | 0.5 | | | | | | | | | |
| Silica-1 | residue | residue | residue | residue | residue | residue | residue | residue | residue | residue | residue | residue | residue |
| Adhesion strength | 830 | 930 | 860 | 780 | 470 | 420 | 410 | 1320 | 1040 | — | — | 130 | 250 |
| after PCT and reflow | | | | | | | | | | | | | |
| [kPa] | | | | | | | | | | | | | |
| Molding | possible | possible | possible | possible | possible | possible | possible | possible | possible | failure | failure | possible | possible |
| Supplying from dispenser | possible | possible | possible | possible | possible | possible | possible | possible | possible | possible | possible | possible | failure |
| Storage stability | good | good | good | good | good | good | good | good | good | good | good | good | poor |

The resin compositions of Comparative examples 3 and 4 had a degree of hardness (#935) at 0 when they were heated at 175° C. for 5 minutes in preparing samples for testing the adhesion strength to copper, and therefore it was found that they could not be molded. On the other hand, although the test sample could be prepared from the composition of Comparative example 6 without any problem, the composition had such poor storage stability that the viscosity was highly increased after stored at 40° C. for 3 hours. Further, its adhesion strength to copper after the PCT and reflow treatment was measured and found to be much inferior to those of Examples 1 to 8.

The above results indicated that, even if the catalysts and/or the ratio between the epoxy resin and the phenol resin were changed within the scope of the present invention, the effect of the present invention could be obtained. Further, it was also revealed that, if the catalyst was used singly, the resultant composition was poor in the adhesion strength to copper after the PCT and reflow treatment and often could not be molded or had poor storage stability.

### Examples 10 to 13

The procedure of Example 1 was repeated, except that the ratio of Catalysts A-1 and B-1 was changed into those shown in Table 2, to prepare resin compositions. With respect to each prepared composition, it was evaluated how much adhesion strength to copper the composition had after the PCT and reflow treatment, whether the composition could be molded, whether the composition could be supplied from a dispenser and whether the composition had satisfying storage stability. The results were shown in Table 2 together with those of Example 1 and Comparative Examples 4 and 6.

TABLE 2

| | Com. | Examples | | | | | Com. |
|---|---|---|---|---|---|---|---|
| | 4 | 10 | 11 | 1 | 12 | 13 | 6 |
| Epoxy a-1 | 12.73 | 12.73 | 12.73 | 12.73 | 12.73 | 12.73 | 12.73 |
| Phenol b-A1 | 6.14 | 6.14 | 6.14 | 6.14 | 6.14 | 6.14 | 6.14 |
| Epoxy silane | 0.5 | 0.5 | 0.5 | 0.5 | 0.5 | 0.5 | 0.5 |
| Catalyst A-1 | 1.5 | 1.35 | 1.125 | 1 | 0.75 | 0.6 | |
| Catalyst B-1 | | 0.15 | 0.375 | 0.5 | 0.75 | 0.9 | 1.5 |
| Silica-1 | residue | residue | residue | residue | residue | residue | residue |
| Adhesion strength | — | 1320 | 1190 | 830 | 660 | 510 | 250 |
| after PCT and reflow | | | | | | | |
| [kPa] | | | | | | | |
| Molding | failure | possible | possible | possible | possible | possible | possible |
| Supplying from dispenser | possible | possible | possible | possible | possible | possible | failure |
| Storage stability | good | good | good | good | good | good | poor |

The above results indicated that the ratio of Catalysts A-1 and B-1 (A-1/B-1) was required to be in the range of 9/1 to 4/6. Further, it was also revealed that, if the amount of A-1 was too large, the resultant composition could not have enough hardness to be molded and that, if the amount of B-1 was too large, the resultant composition was poor not only in the adhesion strength to copper after the PCT and reflow treatment but also in storage stability.

### Examples 14 to 16

The procedure of Example 1 was repeated, except that the total amount of Catalysts A-1 and B-1 was changed into those shown in Table 3, to prepare resin compositions. With respect to each prepared composition, it was evaluated how much adhesion strength to copper the composition had after the PCT and reflow treatment, whether the composition could be molded, whether the composition could be supplied from a dispenser and whether the composition had satisfying storage stability. The results were shown in Table 3 together with that of Example 1.

TABLE 3

| | Examples | | | |
|---|---|---|---|---|
| | 14 | 15 | 1 | 16 |
| Epoxy a-1 | 12.73 | 12.73 | 12.73 | 12.73 |
| Phenol b-A1 | 6.14 | 6.14 | 6.14 | 6.14 |
| Epoxy silane | 0.5 | 0.5 | 0.5 | 0.5 |
| Catalyst A-1 | 0.33 | 0.67 | 1 | 1.33 |
| Catalyst B-1 | 0.17 | 0.33 | 0.5 | 0.67 |
| Silica-1 | residue | residue | residue | residue |
| Adhesion strength | 800 | 850 | 830 | 1570 |
| after PCT and reflow | | | | |
| [kPa] | | | | |
| Molding | possible | possible | possible | possible |
| Supplying from dispenser | possible | possible | possible | possible |
| Storage stability | good | good | good | good |

The above results indicated that, if the total amount of the catalysts was in the range of 0.5 to 2 wt. % based on the total weight of the resin composition, the resultant composition was excellent in the adhesion strength to copper after the PCT and reflow treatment.

### Examples 17 to 20 and Comparative Examples 7 to 8

The procedure of Example 1 was repeated, except that the components (a) and (b), the spherical fused silica particles and the amounts thereof were changed into those shown in Table 4, to prepare resin compositions. With respect to each prepared composition, it was evaluated how much adhesion strength to copper the composition had after the PCT and reflow treatment, whether the composition could be molded, whether the composition could be supplied from a dispenser and whether the composition had satisfying storage stability. The results were shown in Table 4.

TABLE 4

| | Examples | | | | | Com. | |
|---|---|---|---|---|---|---|---|
| | 1 | 17 | 18 | 19 | 20 | 7 | 8 |
| Epoxy a-1 | 12.73 | | 16.07 | 11.36 | 9.34 | | 13.9 |
| Epoxy a-2 | | 12.02 | | | | | |
| Epoxy a-3 | | | | | | 15.82 | |
| Phenol b-A1 | 6.14 | 6.85 | 7.8 | 5.51 | 4.53 | 3.05 | |
| Phenol b-A2 | | | | | | | 4.97 |
| Epoxy silane | 0.5 | 0.5 | 0.5 | 0.5 | 0.5 | 0.5 | 0.5 |
| Catalyst A-1 | 1 | 1 | 1 | 1 | 1 | 1 | 1 |
| Catalyst B-1 | 0.5 | 0.5 | 0.5 | 0.5 | 0.5 | 0.5 | 0.5 |
| Silica-1 | residue | residue | residue | | | residue | residue |
| Silica-2 | | | | residue | residue | | |
| Adhesion strength | 830 | 760 | 1410 | 850 | 690 | 310 | 260 |
| after PCT and reflow | | | | | | | |
| [kPa] | | | | | | | |
| Molding | possible | possible | possible | possible | possible | possible | possible |
| Supplying from dispenser | possible | possible | possible | possible | possible | failure | failure |
| Storage stability | good | good | good | good | good | good | good |

The results of Examples 17 to 20 indicated that, even if the resin components and the silica particles were changed within the scope of the present invention, the obtained composition was excellent in the adhesion strength to copper after the PCT and reflow treatment. In Comparative Examples 7 and 8, generally used epoxy and phenol resins having large molecular weights were used. Those resins were out of the scope of the present invention, and therefore the compositions comprising them were poor in the adhesion strength to copper after the PCT and reflow treatment. Further, it was also found that, since having high viscosity, those compositions could not be supplied from a dispenser.

### Example 21

### Preparation of Resin Composition

In a multipurpose mixer (2DMV-R™, available from Dalton Co., Ltd.), 8.6 wt. % of Epoxy a-1, 10.27 wt. % of Acid anhydride b-B1, 0.5 wt. % of Epoxy silane and Silica-1 were placed and mixed at 80° C. for 2 hours while the mixing chamber was being evacuated. Thereafter, the temperature was brought down to 60° C., and then a solution in which 1 wt. % of Catalyst A-1 and 0.5 wt. % of Catalyst B-1 were dissolved in 3 wt. % acid anhydride was added and mixed for 10 minutes to obtain a resin composition. In the above, Silica-1 was added in the residual amount, which corresponded to the difference between the weight of the resultant composition and the total weight of the other components. The obtained composition could be supplied from a dispenser, and was found to be excellent in storage stability. It was also found that the adhesion strength of the composition to copper was 520 kPa after the PCT and reflow treatment.

### Example 22

The procedure of Example 21 was repeated, except that the epoxy resin was replaced with Epoxy a-2, to prepare a resin composition. The obtained composition could be supplied from a dispenser, and was found to be excellent in storage stability. It was also found that the adhesion strength of the composition to copper was 480 kPa after the PCT and reflow treatment.

### Example 23

The procedure of Example 21 was repeated, except that the acid anhydride was replaced with Acid anhydride b-B2, to prepare a resin composition. The obtained composition could be supplied from a dispenser, and was found to be excellent in storage stability. It was also found that the adhesion strength of the composition to copper was 550 kPa after the PCT and reflow treatment.

### Comparative Example 9

The procedure of Example 21 was repeated, except that the acid anhydride was replaced with Acid anhydride b-B3, to prepare a resin composition. The obtained composition could be supplied from a dispenser, and was found to be excellent in storage stability. It was also found that the adhesion strength of the composition to copper was 480 kPa after the PCT and reflow treatment. However, it was still also found that the weight decreased after the composition was subjected to the PCT at 127° C. for 500 hours. This was presumed to be caused by hydrolysis. Accordingly, it was revealed that there was some question about its long-term reliability.

### Examples 24 to 26

The procedure of Example 21 was repeated, except that Phenol b-A2, Phenol-1 or Phenol-2 was used together with the acid anhydride, to prepare resin compositions. All the obtained compositions could be supplied from a dispenser, and were found to be excellent in storage stability. It was also found that the adhesion strengths of the compositions to copper were 810 kPa, 1020 kPa and 1040 kPa, respectively, after the PCT and reflow treatment. The results of Comparative Example 9 and Examples 21 to 26 were as set forth in Table 5.

TABLE 5

| | Examples | | | Com. | Examples | | |
|---|---|---|---|---|---|---|---|
| | 21 | 22 | 23 | 9 | 24 | 25 | 26 |
| Epoxy A | 8.6 | | 10.3 | 10.64 | 10.86 | 10.42 | 10.14 |
| Epoxy B | | 8.33 | | | | | |
| Acid anhydride A | 10.27 | 11.67 | | | 7.66 | 7.35 | 7.15 |
| Acid anhydride B | | | 9.7 | | | | |
| Acid anhydride C | | | | 9.36 | | | |
| Phenol A | | | | | 1.48 | | |
| Phenol B | | | | | | 2.24 | |
| Phenol C | | | | | | | 2.7 |
| Epoxy silane | 0.5 | 0.5 | 0.5 | 0.5 | 0.5 | 0.5 | 0.5 |
| Catalyst A-1 | 1 | 1 | 1 | 1 | 1 | 1 | 1 |
| Catalyst B-1 | 0.5 | 0.5 | 0.5 | 0.5 | 0.5 | 0.5 | 0.5 |
| Silica-1 | residue | residue | residue | residue | residue | residue | residue |
| Adhesion strength | 520 | 480 | 550 | 480 | 810 | 1020 | 1040 |
| after PCT and reflow | | | | | | | |
| [kPa] | | | | | | | |
| Molding | possible | possible | possible | possible | possible | possible | possible |
| Supplying from dispenser | possible | possible | possible | possible | possible | possible | possible |
| Storage stability | good | good | good | good | good | good | good |
| Long-term PCT durability | good | good | good | poor | good | good | good |

As described above, the present invention provides a liquid resin composition which has excellent adhesion strength to copper after PCT and reflow treatment, which can be advantageously molded, which can be supplied from a dispenser and which has satisfying storage stability.

1. A resin composition comprising:
(I) a resin component (a) selected from bisphenol type epoxy resins having polymerization degrees of 3 or less;
(II) a component (b) selected from the group consisting of:
(i) phenol resins represented by the formula (1A): 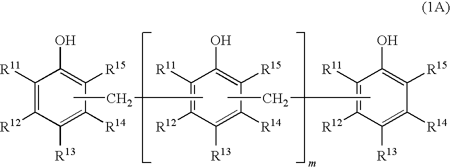
wherein m is a number of 0 to 3, and each of R¹¹ to R¹⁵ is H or an allyl group provided that at least one of R¹¹ to R¹⁵ is an allyl group, and
(ii) acid anhydrides represented by the formula (1B): 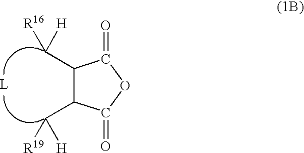
where L is a divalent linking group represented by 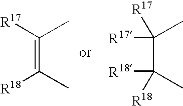
and each of R¹⁶, R¹⁷R^{17′}, R¹⁸, R^{18′} and R¹⁹ is independently H or a hydrocarbon group containing 8 or less carbon atoms provided that at least two of R¹⁶, R¹⁷, R^{17′}, R¹⁸, R^{18′} and R¹⁹ are hydrocarbon groups;
(III) a catalyst (A) represented by one of the formulas (2A), (2B) and (2C): 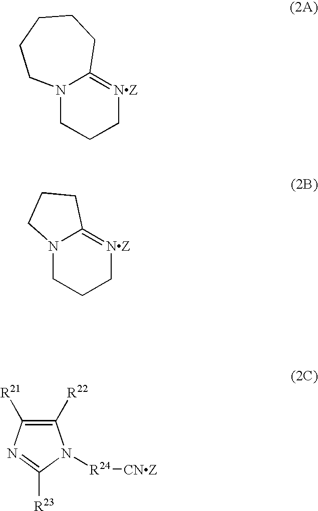
wherein each of R²¹ to R²⁴ is H or a hydrocarbon group which may be substituted with hydroxyl or cyano, and Z is a compound selected from the group consisting of sulfonic acids, carboxylic acids, phenols and phenol resins;
(IV) a catalyst (B) represented by one of the formulas (3A), (3B) and (3C): 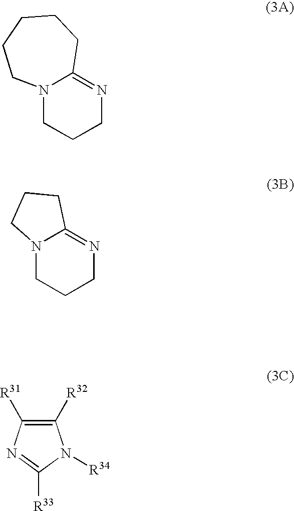
wherein each of R³¹ to R³⁴ is H or a hydrocarbon group which may be substituted with hydroxyl or cyano; and
(V) spherical fused silica particles;
under the condition that the weight ratio (A/B) between the catalyst (A) and the catalyst (B) is in the range of 9/1 to 4/6.

2. The resin composition according to claim 1, wherein said epoxy resins are bisphenol A type epoxy resins.

3. The resin composition according to claim 2, wherein said epoxy resins are represented by the following formula (4):

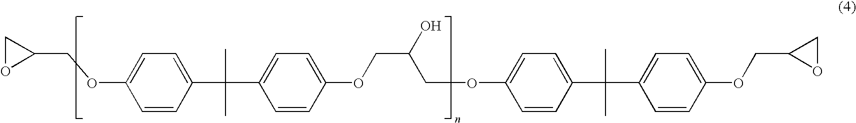

4. The resin composition according to claim 1, wherein the total amount of the catalyst (A) and the catalyst (B) is in the range of 0.5 to 2 wt. % based on the total weight of the resin composition.

5. The resin composition according to claim 1, wherein said catalyst (A) is 1-cyanoethyl-2-undecylimidazolium trimellitate.

6. The resin composition according to claim 1, wherein said catalyst (B) is 1-cyanoethyl-2-ethyl-4-methylimidazole, 2-phenylimidazole or 2-phenyl-4,5-dihydroxymethylimidazole.

7. The resin composition according to claim 1, wherein said spherical fused silica particles have a mean particle size of 1 to 50 μm.

8. The resin composition according to claim 1, characterized by further comprising another phenol resin other than those represented by the formula (1A).

9. The resin composition according to claim 8, wherein said another phenol resin other than those represented by the formula (1A) has a melting point or a softening point at a temperature of 70° C. or below.

10. The resin composition according to claim 8, wherein said phenol resin other than those represented by the formula (1A) has a structure represented by one of the following formulas (5A) to (5C): 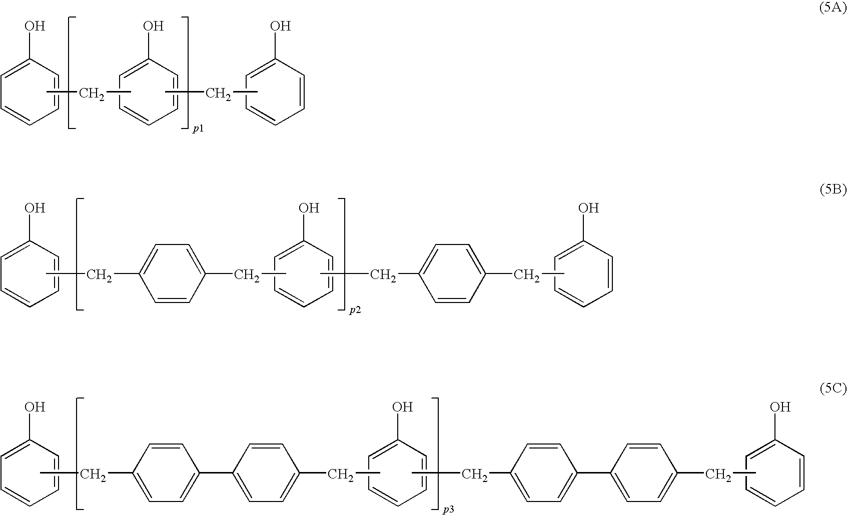
wherein p1, p2 and p3 are numbers indicating polymerization degrees.

11. The resin composition according to claim 1, characterized by having an adhesion strength to oxygen-free copper in the range of 0.4 MPa or more after left at 127° C. for 96 hours under the saturated vapor pressure and then passed three times through a reflow furnace at 280° C. for 30×3 seconds.

12. A semiconductor device, characterized by being sealed with the resin composition according to claim 1.
